(19) United States
(12) Patent Application Publication
(10) Pub. No.: US 2009/0057564 A1
(43) Pub. Date: Mar. 5, 2009

(54) PHOTOSENSOR AND X-RAY IMAGING DEVICE

(75) Inventors: Takashi MIYAYAMA, Tokyo (JP); Hiroyuki Murai, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MITSUBISHI ELECTRIC CORPORATION, Chiyoda-ku (JP)

(21) Appl. No.: 12/202,628

(22) Filed: Sep. 2, 2008

(30) Foreign Application Priority Data
Sep. 3, 2007 (JP) 2007-227292

(51) Int. Cl. G01T 1/24; H01L 27/146

(52) U.S. Cl. 250/370.09; 257/292

(57) ABSTRACT

A parasitic capacitance is reduced between a lower electrode of a photodiode and data line. A photosensor according to this invention includes a glass substrate; an underlying insulator which is provided on the glass substrate, and has a dielectric constant lower than that of the glass substrate; and a switching element which is formed by laminating a gate electrode, a gate insulating film, and a semiconductor layer on the underlying insulator, and includes a drain electrode connected to the semiconductor layer. The drain electrode has an extended portion which directly contacts a surface of the underlying insulator. The photosensor further includes a photodiode which is provided on the extended portion of the drain electrode.

### BACKGROUND OF THE INVENTION

1. Field of the Invention

The present invention relates to a photosensor including a photodiode and a switching element as well as an X-ray imaging device.

2. Description of the Background Art

A photosensor includes a flat panel formed by a Thin Film Transistor (hereinafter referred to as TFT) array substrate in which photodiodes performing photoelectric conversion of visible light and the TFTs are arranged in a matrix shape. The photosensor is widely applied to a contact image sensor and an X-ray imaging display device. Particularly, a flat panel X-ray imaging display device (hereinafter referred to as FPD) in which a scintillator converting an X-ray into the visible light is provided on the TFT array substrate is a promising device applied to the medical industry and the like.

The use of a fine image (still image) and a real-time image observation (moving image) are separated in the field of X-ray image diagnosis. An X-ray film is mainly used even now to take the still image. On the other hand, an image pickup tube (image intensifier) in which a photomultiplier tube and CCD (Charge Coupled Device) are combined is used to take the moving image. There are merits and demerits in the X-ray film and the image pickup tube. The X-ray film has a merit of high spatial resolution. However, the X-ray film has low sensitivity, and only the still image can be taken in the X-ray film. The X-ray film lacks readiness because a development process is required after taking the image. On the other hand, the image pickup tube has the high sensitivity, and the image pickup tube can take the moving image. However, the image pickup tube has the low spatial resolution, and there is a limitation to upsizing of the image pickup tube because the image pickup tube is a device produced through a vacuum process.

In FPD, there are an indirect conversion method and a direct conversion method. In the indirect conversion method, the X-ray is converted into the light by the scintillator made of CsI or the like, and the light is converted into a charge by the photodiode. In the direct conversion method, the X-ray is directly converted into the charge by an X-ray detection element typically made of Se. Compared with the direct conversion method, the indirect conversion method has higher quantum efficiency and excellent signal/noise ratio. Therefore, in the indirect conversion method, the perspective and the image can be taken with a smaller exposure amount. For example, Japanese Patent Application Laid-Open No. 2004-63660 discloses a structure and a production method relating to the TFT array substrate constituting the FPD of the indirect conversion type.

In order to read a signal of the photosensor with high sensitivity or to improve an operating speed (frame rate) of a read-out circuit, it is necessary to decrease parasitic capacitances added to a data interconnection, a bias interconnection, and a gate interconnection. The parasitic capacitances added to the data interconnection, bias interconnection, and gate interconnection include not only a capacitance component generated by intersection between interconnections but also a capacitance component generated by a fringe effect of each interconnection.

However, in FPD, there is a large region where the gate line, the data line, and the photodiode are disposed in parallel, which causes a problem in that the large parasitic capacitance is generated between each interconnection and a upper electrode and a lower electrode of the photodiode.

### SUMMARY OF THE INVENTION

An object of the present invention is to provide a photosensor which can reduce a parasitic capacitance between a lower electrode of a photodiode and a data line.

In accordance with the present invention, the photosensor includes a substrate, an insulating film, a switching element, and a photodiode. The insulating film is provided on the substrate and has a dielectric constant lower than that of the substrate. The switching element is formed by laminating a gate electrode, a gate insulating film, and a semiconductor layer on the insulating film, and includes an electrode connected to the semiconductor layer. The electrode has an extended portion which directly contacts a surface of the insulating film. The photodiode is provided on the extended portion of the electrode.

Accordingly, the parasitic capacitance can be reduced between the lower electrode of the photodiode and the data line.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a front view of a photosensor according to First Embodiment;

FIG. 2 is a sectional view of the photosensor according to First Embodiment;

FIG. 3 is a sectional view of a conventional photosensor; and

FIG. 4 shows an effect of the photosensor according to First Embodiment.

### DESCRIPTION OF THE PREFERRED EMBODIMENTS

### First Embodiment

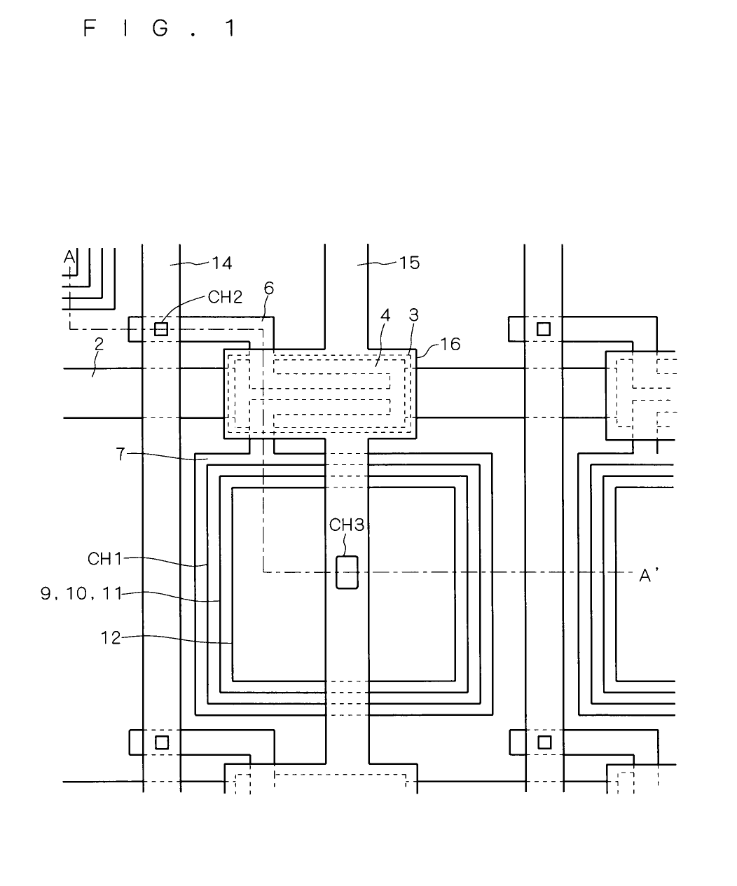

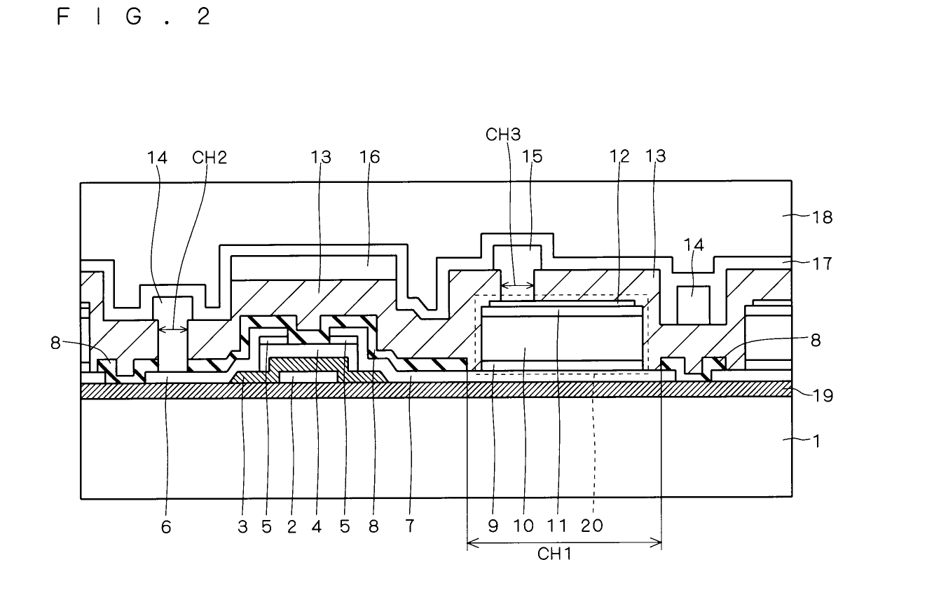

FIG. 1 is a plan view of a TFT (Thin Film Transistor) array substrate included in a photosensor according to the present embodiment. FIG. 2 is a sectional view taken on a line A-A′ of FIG. 1. As shown in FIG. 2, the photosensor according to the present embodiment includes a glass substrate 1, an underlying insulator 19, a thin film transistor (hereinafter referred to as TFT), a photodiode 20, and first to fourth passivation films 8, 13, 17, and 18. In the present embodiment, as shown in FIG. 1, the TFTs and photodiodes 20 are arranged in a matrix shape.

The glass substrate 1 which is of a substrate has an insulating property. The underlying insulator 19 which is of an insulating film is provided on the glass substrate 1, and the underlying insulator 19 has a dielectric constant lower than that of the glass substrate 1. For example, the underlying insulator 19 is formed by a silicon oxide film or an SiOF (FSG) film in which fluorine is contained in a silicon oxide. In the present embodiment, it is assumed that the underlying insulator 19 is made of the silicon oxide.

The TFT which is of a switching element is formed by laminating a gate electrode 2, a gate insulating film 3, and a semiconductor layer 4 on the underlying insulator 19, and the TFT includes a drain electrode 7 which is of an electrode connected to the semiconductor layer 4. In the present embodiment, the TFT also includes an ohmic contact layer 5 and a source electrode 6.

The gate electrode 2 is formed on the underlying insulator 19. A low-resistance metal such as a metal mainly containing aluminum (Al) is used as a material of the gate electrode 2. As used herein, the metal mainly containing Al shall mean an Al alloy containing nickel (Ni) such as AlNiNd, AlNiSi, and AlNiMg, that is, an Al—Ni alloy. However, the metal mainly containing aluminum Al is not limited to the Al—Ni alloy, but other Al alloys may be used. In addition to Al, the gate electrode 2 may be made of a low-resistance metal material such as copper (Cu).

The gate insulating film 3 is formed such that the gate electrode 2 is covered therewith. In the present embodiment, as shown in FIG. 2, the gate insulating film 3 is formed only around the gate electrode 2. The semiconductor layer 4 is formed on the gate insulating film 3 so as to face the gate electrode 2. For example, the semiconductor layer 4 is made of a-Si:H (amorphous silicon to which a hydrogen atom is added). The ohmic contact layer 5 is formed on the semiconductor layer 4. For example, the ohmic contact layer 5 is made of an n⁺-conductive type a-Si:H.

Each of the source electrode 6 and the drain electrode 7 is formed so as to be connected to the semiconductor layer 4 with the ohmic contact layer 5 interposed therebetween. As shown in FIG. 1, the drain electrode 7 includes an extended portion which directly contacts a surface of the underlying insulator 19.

The first passivation film 8 is formed on the semiconductor layer 4, the source electrode 6, the drain electrode 7, and the underlying insulator 19. A contact hole CH1 opened on the extended portion of the drain electrode 7 is made in the first passivation film 8.

The photodiode 20 is provided inside the contact hole CH1, and the photodiode 20 is provided on the extended portion of the drain electrode 7. Therefore, the extended portion of the drain electrode 7 corresponds to a lower electrode of the photodiode 20. In the present embodiment, the photodiode 20 has a three-layer laminated structure, that is, the photodiode 20 includes a P-doped amorphous silicon film 9, an intrinsic amorphous silicon film 10 formed on the P-doped amorphous silicon film 9, and a B-doped amorphous silicon film 11 formed on the intrinsic amorphous silicon film 10. A transparent electrode 12 made of IZO, ITZO, and ITSO is formed on the photodiode 20.

A second passivation film 13 which is formed such that the above-described configuration is covered therewith has contact holes CH2 and CH3. A part of a data line 14 is embedded in the contact hole CH2, and a part of a bias line 15 is embedded in the contact hole CH3. The data line 14 and the bias line 15 are formed on the second passivation film 13. The data line 14 is formed so as to be connected to the source electrode 6 through the contact hole CH2. The bias line 15 is formed so as to be connected to the transparent electrode 12 through the contact hole CH3.

For example, the data line 14 and the bias line 15 is formed by a conductive material, in which an Al—Ni alloy film is provided in at least an uppermost layer, or a lowermost layer or a single-layer Al—Ni alloy film. In the case where the Al—Ni alloy film is formed in the uppermost layer, a nitriding layer may further be provided in a surface of the uppermost layer. The data line 14 is an interconnection which is used to read a charge converted by the photodiode 20 having the three-layer laminated structure. The bias line 15 is an interconnection which is used to apply a reverse bias to the photodiode 20 having the three-layer laminated structure in order to set the photodiode 20 at an off state when light does not shine on the photodiode 20.

A light shielding layer 16 is also formed on the second passivation film 13. The third passivation film 17 and the fourth passivation film 18 are formed such that the above-described constituents are covered therewith. The fourth passivation film 18 has a flat surface, and the fourth passivation film 18 is made of, for example, an organic resin.

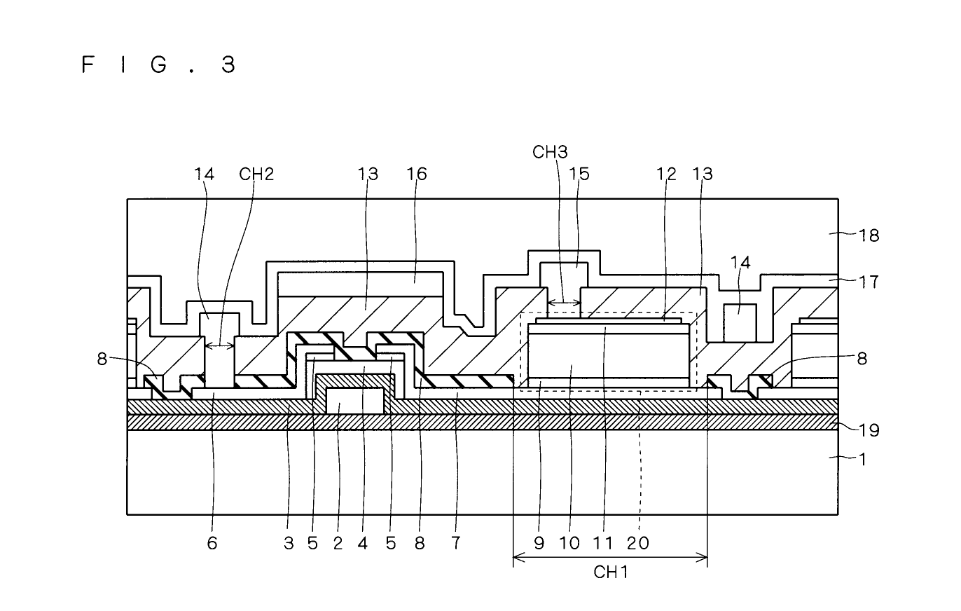

For the purpose of comparison, FIG. 3 shows a sectional view of a conventional photosensor. In FIG. 3, the same configuration as that of FIGS. 1 and 2 is designated by the same numeral. In the conventional photosensor, the gate insulating film 3 is extended to a region below the photodiode 20. On the other hand, in the photosensor of the present embodiment, the gate insulating film 3 is not extended to the region below the photodiode 20. As a result, the photosensor of the present embodiment differs from the conventional photosensor in that only the underlying insulator 19 is provided in a region between the glass substrate 1 and the extended portion of the drain electrode 7 corresponding to the lower electrode of the photodiode 20.

An example of a method for producing the TFT array substrate included in the photosensor of the present embodiment will be described below. First the underlying insulator 19 made of the silicon oxide whose dielectric constant is lower than that of the glass substrate 1 is formed on the glass substrate 1 by a plasma CVD technique. As described later, an advantage of reducing the parasitic capacitance between the lower electrode of the photodiode 20 and the data line 14 is increased with increasing thickness of the underlying insulator 19. A film having the low dielectric constant, such as a silicon oxide film (HSQ) film containing a Si—H bond, which can be formed by a coating method may be formed on the glass substrate 1 for the purpose of simplified process. In the case where the SiOF (FSG) film is used as the underlying insulator 19, similarly to the silicon oxide film, the SiOF (FSG) film can be formed by the plasma CVD technique.

Then, in order to form the gate electrode 2, a metal containing Al, for example the Al alloy containing Ni such as AlNiNd is formed as a first conductive thin film by a sputtering technique. For example, the first conductive thin film is deposited under the following conditions: a pressure ranges from 0.2 to 0.5 Pa, DC power ranges from 1.0 to 2.5 kW, that is, from 0.17 to 0.43 W/cm² in terms of power density, and a depositing temperature ranges from room temperature to 180° C. The thickness of the first conductive thin film ranges from 150 to 300 nm. A nitrided AlNiNdN layer may be formed on AlNiNd in order to suppress a reaction with a development solution. For example, AlNiSi and AlNiMg may be used instead of AlNiNd. The data line 14 and the bias line 15 may be made of the same material in order to enhance production efficiency. In addition to Al, Cu or a Cu alloy can be used as the low-resistance material. In such cases, Cu or a Cu alloy can also be deposited by the sputtering technique.

Then, through a first photolithographic process, a resist (not shown) having a shape of the gate electrode 2 is patterned, and the first conductive thin film is patterned to form the gate electrode 2 using a mixed acid of a phosphoric acid, a nitric acid, and an acetic acid through an etching process. When the gate electrode 2 is formed into a tapered shape in section, a defect such as an open circuit can be reduced in the subsequent film formation. Although the mixed acid of the phosphoric acid, nitric acid, and acetic acid is used in the present embodiment, a kind of the etching solution is not limited to the mixed acid of the phosphoric acid, nitric acid, and acetic acid. The etching is not limited to wet etching, but dry etching may be used. Because the structure in which the gate electrode 2 is not exposed in forming the photodiode 20 is adopted in the present embodiment, the gate electrode 2 can be made of the metal mainly containing Al or Cu which is not so strong against damage. Therefore, the low-resistance interconnection can be made to form a large photosensor.

Then, the gate insulating film 3, the semiconductor layer 4 made of a-Si:H (amorphous silicon to which a hydrogen atom is added), and the ohmic contact layer 5 made of the n⁺-conductive type a-Si:H are sequentially deposited by the plasma CVD technique such that the thickness of the gate insulating film 3 ranges from 200 to 400 nm, such that the thickness of the semiconductor layer 4 ranges from 100 to 200 nm, and such that the thickness of the ohmic contact layer 5 ranges from 20 to 50 nm. Desirably, a silicon nitride film, a silicon oxynitride film, or a film having a two-layer structure of the silicon oxynitride film and the silicon oxide film is used as the gate insulating film 3.

High charge read-out efficiency is demanded for the photosensor, and the TFT having high driving performance is required to realize the high charge read-out efficiency. Therefore, the semiconductor layer 4 made of a-Si:H is divided into two steps to perform the depositing, thereby enhancing the performance of the TFT. For the depositing condition in this case, a high-quality film is formed at a low depositing rate of 50 to 200 Å/min in the first layer, and a remaining film is formed at a depositing rate of at least 300 Å/min. The gate insulating film 3, the semiconductor layer 4, and the ohmic contact layer 5 are deposited at a depositing temperature of 250 to 350° C.

Then, a resist (not shown) having a channel shape is formed through a second photolithographic process, and the semiconductor layer 4 and the ohmic contact layer 5 are patterned into an island shape through the etching process such that a portion where a channel is formed is left. The etching is performed by plasma in which a mixed gas of SF₆ and HCl is used. When the channel is formed into a tapered shape in section, a defect such as an open circuit can be reduced in the subsequent film formation. Although the mixed gas of SF₆ and HCl is used as the etching gas in the present embodiment, a kind of the etching gas is not limited to the mixed gas of SF₆ and HCl.

Then, through a third photolithographic process, at least the gate insulating film 3 located below the photodiode 20 is removed by the etching process. In the present embodiment, the gate insulating film 3 is removed so as to be formed only around the gate electrode 2. When the gate insulating film 3 is formed into a tapered shape in section, a defect such as an open circuit can be reduced in the subsequent film formation.

Then, a second conductive thin film is deposited. The second conductive thin film is formed by depositing a refractory metal film such as chromium (Cr) by the sputtering technique. The second conductive thin film is formed such that the thickness ranges from 50 to 300 nm.

Then, a resist (not shown) corresponding to the patterning of the source electrode 6 and drain electrode 7 is formed through a fourth photolithographic process, and the second conductive thin film is patterned using a mixed acid of cerium ammonium nitrate and the nitric acid through the etching process. Therefore, the source electrode 6 and the drain electrode 7 are formed. Then, while the formed electrodes are masked, the ohmic contact layer 5 is etched to form the TFT using plasma in which the mixed gas of SF₆ and HCl is used.

In the present embodiment, the mixed acid of the cerium ammonium nitrate and the nitric acid is used as the etching solution to form the source electrode 6 and the drain electrode 7, and the mixed gas of SF₆ and HCl is used as the etching gas of the ohmic contact layer 5. However, the present invention is not limited to the mixed acid of the cerium ammonium nitrate and the nitric acid and the mixed gas of SF₆ and HCl. In the present embodiment, the source electrode 6 and the drain electrode 7 are made of Cr. However, the materials of the source electrode 6 and drain electrode 7 are not limited to Cr, but any metal except for Cr may be used as long as ohmic contact is established between the metal and Si. Further, the first passivation film 8 is formed after the electrodes are formed. Alternatively, before the first passivation film 8 is formed, a plasma process may be performed using a hydrogen gas to roughen a back channel side, that is, the surface of the semiconductor layer 4 in order to enhance the characteristics of the TFT.

Then, a passivation film is formed by the plasma CVD technique. Through a fifth photolithographic process, the contact hole CH1 is patterned using a resist (not shown) in order to establish contact between the drain electrode 7 and the P-doped amorphous silicon film 9. The patterning is performed by etching the passivation film, thereby forming the first passivation film 8.

The passivation film is etched using plasma in which a mixed gas of CF₄ and O₂ is used. In the first passivation film 8, the low dielectric constant silicon oxide (SiO₂) film is formed with the thickness of 200 to 400 nm. For example, the silicon oxide film is deposited under the following conditions: a SiH₄ flow rate ranges from 10 to 50 sccm, an N₂O flow rate ranges from 200 to 500 sccm, a depositing pressure is 50 Pa, RF power ranges from 50 to 200 W, that is, from 0.015 to 0.67 W/cm² in terms of power density, and a depositing temperature ranges from 200 to 300° C. Although the mixed gas of CF₄ and O₂ is used as the etching gas, a kind of the etching gas is not limited to the mixed gas of CF₄ and O₂. In the present embodiment, the first passivation film 8 is made of the silicon oxide. However, the first passivation film 8 is not limited to the silicon oxide, but the first passivation film 8 may be made of SiN or SiON. In such cases, the first passivation film 8 is formed while hydrogen, nitrogen, and ammonia (NH₃) are added to the mixed gas of CF₄ and O₂.

In order to form the photodiode 20 by the plasma CVD technique, a P-doped amorphous silicon film, an intrinsic amorphous silicon film, and a B-doped amorphous silicon film are sequentially deposited with the same character film while vacuum is not broken. For the purpose of convenience, hereinafter the P-doped amorphous silicon film, the intrinsic amorphous silicon film, and the B-doped amorphous silicon film are referred to as amorphous silicon layer. At this point, the P-doped amorphous silicon film is formed such that the thickness ranges from 30 to 80 nm, the intrinsic amorphous silicon film is formed such that the thickness ranges from 0.5 to 0.2 μm, and the B-doped amorphous silicon film is formed such that the thickness ranges from 30 to 80 nm.

For example, the intrinsic amorphous silicon film is deposited under the following conditions: the SiH₄ flow rate ranges from 100 to 200 sccm, an H₂ flow rate ranges from 100 to 300 sccm, the depositing pressure ranges from 100 to 300 Pa, the RF power ranges from 30 to 150 W, that is, from 0.01 to 0.05 W/cm² in terms of power density, and the depositing temperature ranges from 200 to 300° C. The P-doped and B-doped silicon films are deposited under the above-described depositing conditions using depositing gases in which 0.2 to 1.0% PH₃ and B₂H₆ are mixed, respectively.

The B-doped amorphous silicon film may be formed by doping B into an upper layer portion of the intrinsic amorphous silicon film by ion shower doping or ion implantation. In the case where the B-doped amorphous silicon film is formed by the ion implantation, an SiO₂ film having a thickness of 5 to 40 nm may be formed on the surface of the intrinsic amorphous silicon film prior to the ion implantation. This is because the damage is reduced in implanting B. In such cases, the SiO₂ film may be removed using BHF (buffer hydrofluoric acid) after the ion implantation.

Then, the non-crystalline transparent conductive film is deposited by the sputtering technique using a target of one of IZO, ITZO, and ITSO. For example, the non-crystalline transparent conductive film is deposited under the following conditions: the depositing pressure ranges from 0.3 to 0.6 Pa, the DC power ranges from 3 to 10 kW, that is, from 0.65 to 2.3 W/cm² in terms of power density, an Ar flow rate ranges from 50 to 150 sccm, an oxygen flow rate ranges from 1 to 2 sccm, and a depositing temperature ranges from room temperature to about 180° C. After the non-crystalline transparent conductive film is deposited, through a sixth photolithographic process, a resist (not shown) is formed, and the etching is performed using an oxalic acid to perform the patterning, thereby forming the transparent electrode 12. Although the oxalic acid is used as the etching solution in the present embodiment, the etching solution is not limited to the oxalic acid. In the present embodiment, because the film containing one of IZO, ITZO, and ITSO is used as the transparent electrode 12, the depositing can be performed in a non-crystalline state in which micro crystal particles is hardly contained in the B-doped amorphous silicon film which is of the lower layer. Accordingly, advantageously an etching residue is hardly generated. Alternatively, a film in which the above-described materials are mixed may be used as the transparent electrode 12, the transparent electrode 12 may have a structure in which films containing materials are laminated, or the transparent electrode 12 may by formed by films in which the materials are mixed.

Through a seventh photolithographic process, a resist pattern larger than the pattern of the transparent electrode 12 is formed so as to be located inside the etching region of the contact hole CH1. A three-layer amorphous silicon layer is patterned using plasma of the mixed gas of SF₆ and HCl. The P-doped amorphous silicon film 9, the intrinsic amorphous silicon film 10, and the B-doped amorphous silicon film 11 are formed by the patterning as shown in FIG. 2. Although the mixed gas of SF₆ and HCl is used as the etching gas, the etching gas is not limited to the mixed gas of SF₆ and HCl. Therefore, the photodiode 20 having the three-layer laminated structure is formed.

Then, a second passivation film is formed to protect the photodiode 20. Then, a resist pattern (not shown) corresponding to the contact hole CH2 connecting the source electrode 6 and the data line 14 and the contact hole CH3 connecting the transparent electrode 12 of the photodiode 20 and the bias line 15 is formed through eighth photolithographic process. The second passivation film is etched using plasma of the mixed gas of CF₄ and Ar, thereby forming the second passivation film 13 having the contact holes CH2 and CH3.

The second passivation film 13 is formed by depositing the low dielectric constant silicon oxide film having the thickness of 0.5 to 1.5 μm in order to reduce additional capacitances added to the data line 14 bias line 15. For example, the silicon oxide film is deposited under the following conditions: the SiH₄ flow rate ranges from 10 to 50 sccm, the N₂O flow rate ranges 200 to 500 sccm, the depositing pressure is 50 Pa, the RF power ranges from 50 to 200 W, that is, from 0.015 to 0.67 W/cm² in terms of power density, and the depositing temperature ranges from 200 to 300° C. Although the second passivation film 13 is made of the silicon oxide, the second passivation film 13 may be made of SiN. In making the contact holes CH2 and CH3, when the contact holes CH2 and CH3 are formed into a tapered shape in section, a coating property can be improved in the upper layer to reduce a defect such as an open circuit.

Then, a third conductive thin film is deposited to form the data line 14, the bias line 15, and the light shielding layer 16. The Ni-contained Al alloy, such as AlNiNd, which has a low resistance, an excellent heat-resistant property, and an excellent contact property with the transparent conductive film is used as the third conductive thin film. The third conductive thin film is deposited such that the thickness ranges from 0.5 to 1.5 μm. The data line 14 and the bias line 15 may be formed by the single layer of AlNiNd or the laminated layer of AlNiNd and the Mo or Mo alloy or AlNiNd and a refractory metal such as Cr. A nitrided AlNiNdN may be formed on AlNiNd in order to suppress a reaction with the development solution. In these films, the Mo alloy is deposited as an underlying layer by the sputtering technique, and AlNiNd is continuously deposited on the Mo alloy. These films are formed under the following depositing conditions: the depositing pressure ranges from 0.2 to 0.5 Pa, the DC power ranges from 1.0 to 2.5 kW, that is, from 0.17 to 0.43 W/Cm² in terms of power density, and the depositing temperature ranges from room temperature to about 180° C.

Then, through a ninth photolithographic process, a resist corresponding to the data line 14, the bias line 15, and the light shielding layer 16 are formed, and the resist is etched to perform the patterning. In the case where the data line 14 and the bias line 15 are formed by the laminated film of AlNiNd and Mo, the patterning is performed using the mixed acid of the phosphoric acid, nitric acid, and acetic acid. Although the mixed acid of the phosphoric acid, nitric acid, and acetic acid is used as the etching solution in the present embodiment, a kind of the etching solution is not limited to the mixed acid of the phosphoric acid, nitric acid, and acetic acid. At this point the data line 14 is connected to the source electrode 6 through the contact hole CH2, and the bias line 15 is connected to the transparent electrode 12 through the contact hole CH3. In the bias line 15, the Al alloy containing Ni or the refractory metal is used as the lowermost layer as described above, a contact resistance is decreased between the bias line 15 and the transparent electrode 12 which is of the lower layer, so that the good connection can be obtained.

Then, the third passivation film 17 and the fourth passivation film 18 are formed to protect the data line 14 and the bias line 15. For example, the third passivation film 17 is made of SiN, and a planarizing film is used as the fourth passivation film 18.

Through a tenth photolithographic process, a resist for a contact hole (not shown) used to obtain the connection to a terminal is formed by the patterning using plasma of the mixed gas of CF₄ and O₂. Although the mixed gas of CF₄ and O₂ is used as the etching gas in the present embodiment, the etching gas is not limited to the mixed gas of CF₄ and O₂. In the tenth photolithographic process, the patterning of the fourth passivation film 18 may be performed by an exposure and development process if the planarizing film having a photosensitive property is used as the fourth passivation film 18.

Then, a conductive film constituting a terminal extraction electrode (not shown) is deposited. The electrode is formed by depositing the transparent conductive film, for example, an amorphous ITO in order to ensure reliability.

Then, through an eleventh photolithographic process, a resist having a terminal shape is formed, and the etching is performed using the oxalic acid to form the terminal extraction electrode. Then, the ITO is crystallized by annealing.

The TFT of the reverse-staggered channel type according to the present embodiment is made of amorphous silicon. Alternatively, a poly-silicon TFT or MOS made of crystalline silicon may be used.

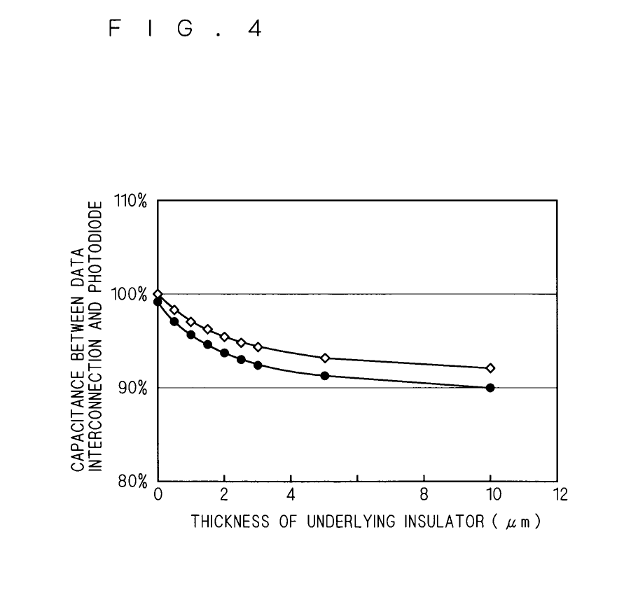

An affect of the photosensor according to the present embodiment will be described based on experimental results. FIG. 4 shows a relationship of the parasitic capacitance between the data line 14 and the extended portion of the drain electrode 7 corresponding to the lower electrode of the photodiode 20 and the thickness of the underlying insulator 19 deposited over the glass substrate 1.

The underlying insulator 19 of FIG. 4 is formed by the plasma CVD technique, and the underlying insulator 19 is formed by the silicon oxide film having specific dielectric constant of about 4. In FIG. 4, a vertical axis indicates a parasitic capacitance in the case where the parasitic capacitance is set at 100% when the underlying insulator 19 is not formed. In FIG. 4, a black circle indicates the photosensor according to the present embodiment shown in FIG. 2, that is, the photosensor in which the gate insulating film 3 below the photodiode 20 is removed. At the same time, an outline square indicates the conventional photosensor of FIG. 3, that is, the photosensor in which the gate insulating film 3 below the photodiode 20 is not removed.

As shown in FIG. 4, in the photosensor according to the present embodiment, the parasitic capacitance can be reduced between the lower electrode of the photodiode 20 and the data line 14 compared with the conventional photosensor. For example, in the case where the silicon oxide film having the thickness of 10 μm is formed as the underlying insulator 19, the parasitic capacitance can be reduced by about 10% in the photosensor of the present embodiment, while the parasitic capacitance is reduced only by 6 to 7% in the conventional photosensor. Thus, according to the photosensor of the present embodiment, the parasitic capacitance can be reduced between the lower electrode of the photodiode 20 and the data line 14.

The X-ray imaging device can be realized with the photosensor. A scintillator (not shown) which is provided above the photosensor to convert the X-ray into light. The scintillator is formed by evaporating CsI on the fourth passivation film 18 or a layer above the fourth passivation film 18. A digital board including a low-noise amplifier and an A/D converter, a driver board which drives the TFT, and a read-out board which reads the charge are connected to the scintillator to form the X-ray imaging device.

Therefore, the X-ray imaging device having the large Signal/Noise (S/N) ratio and the large frame rate can be realized.

While the invention has been shown and described in detail, the foregoing description is in all aspects illustrative and not restrictive. It is therefore understood that numerous modifications and variations can be devised without departing from the scope of the invention.

What is claimed is:

1. A photosensor comprising:
a substrate;
an insulating film which is provided on said substrate, and has a dielectric constant lower than that of said substrate;
a switching element which is formed by laminating a gate electrode, a gate insulating film, and a semiconductor layer on said insulating film, and includes an electrode connected to said semiconductor layer,
said electrode including an extended portion which directly contacts a surface of said insulating film; and
a photodiode which is provided on said extended portion of said electrode.

2. The photosensor according to claim 1, wherein a material of said insulating film contains a silicon oxide.

3. An X-ray imaging device comprising:
a photosensor which includes;
a substrate,
an insulating film which is provided on said substrate, and has a dielectric constant lower than that of said substrate,
a switching element which is formed by laminating a gate electrode, a gate insulating film, and a semiconductor layer on said insulating film, and includes an electrode connected to said semiconductor layer,
said electrode having an extended portion which directly contacts a surface of said insulating film, and
a photodiode which is provided on said extended portion of said electrode; and
a scintillator which is provided above said photodiode to convert an X-ray into light.
